(19) United States
(12) Patent Application Publication
(10) Pub. No.: US 2015/0263706 A1
(43) Pub. Date: Sep. 17, 2015

(54) SEMICONDUCTOR INTEGRATED CIRCUIT

(71) Applicant: Kabushiki Kaisha Toshiba, Tokyo (JP)

(72) Inventor: Atsushi Nakayama, Yokohama Kanagawa (JP)

(21) Appl. No.: 14/483,891

(22) Filed: Sep. 11, 2014

(30) Foreign Application Priority Data
Mar. 13, 2014 (JP) 2014-049983

(51) Int. Cl. H03K 3/037; H03K 19/20

(52) U.S. Cl. CPC H03K 3/037; H03K 3/0372; H03K 19/20

(57) ABSTRACT

According to one embodiment, a semiconductor integrated circuit comprises primitive cells and lines connecting to the primitive cells. The primitive cell comprises a negative logic flip-flop and one stage of a clock buffer that inputs a clock to the negative logic flip-flop.

### CROSS-REFERENCE TO RELATED APPLICATIONS

This application is based upon and claims the benefit of priority from Japanese Patent Application No. 2014-49983, filed on Mar. 13, 2014; the entire contents of which are incorporated herein by reference.

### FIELD

Embodiments described herein relate generally to a semiconductor integrated circuit.

### BACKGROUND

In semiconductor integrated circuits, flip-flops to form a sequential circuit may be used in plurality. Accordingly, in reducing the power consumption of the semiconductor integrated circuit, it is effective to reduce the power consumption of the flip-flops.

### BRIEF DESCRIPTION OF THE DRAWINGS

FIG. 1 is a block diagram showing schematically the configuration of a semiconductor integrated circuit according to a first embodiment;

FIG. 2 is a block diagram showing the configuration of a flip-flop applied to a semiconductor integrated circuit according to a second embodiment;

FIG. 3 is a circuit diagram showing a specific example of the flip-flop of FIG. 2;

FIG. 4 is a block diagram showing the configuration of a flip-flop applied to a semiconductor integrated circuit according to a third embodiment;

FIG. 5 is a circuit diagram showing a specific example of the flip-flop of FIG. 4;

FIG. 6 is a block diagram showing the configuration of a flip-flop applied to a semiconductor integrated circuit according to a fourth embodiment;

FIG. 7 is a circuit diagram showing a specific example of the flip-flop of FIG. 6;

FIG. 8 is a block diagram showing the configuration of a flip-flop applied to a semiconductor integrated circuit according to a fifth embodiment;

FIG. 9 is a circuit diagram showing a specific example of the flip-flop of FIG. 8;

FIG. 10 is a circuit diagram showing the configuration of a flip-flop applied to a semiconductor integrated circuit according to a sixth embodiment;

FIG. 11 is a circuit diagram showing the configuration of a flip-flop applied to a semiconductor integrated circuit according to a seventh embodiment;

FIG. 12 is a circuit diagram showing the configuration of a flip-flop applied to a semiconductor integrated circuit according to an eighth embodiment;

FIG. 13 is a circuit diagram showing the configuration of a flip-flop applied to a semiconductor integrated circuit according to a ninth embodiment;

FIG. 14 is a plan view showing an example layout of primitive cells in a semiconductor integrated circuit according to a tenth embodiment; and

FIG. 15 is a block diagram showing schematically the configuration of a semiconductor integrated circuit according to an eleventh embodiment.

### DETAILED DESCRIPTION

According to one embodiment, a semiconductor integrated circuit comprises primitive cells which are circuit elements used in automatic placement and routing by computing, and lines connecting to the primitive cells. The primitive cell comprises a negative logic flip-flop and one stage of a clock buffer that inputs a clock to the negative logic flip-flop. The semiconductor integrated circuits according to embodiments will be described in detail below with reference to the accompanying drawings.

The present invention is not limited to these embodiments.

### First Embodiment

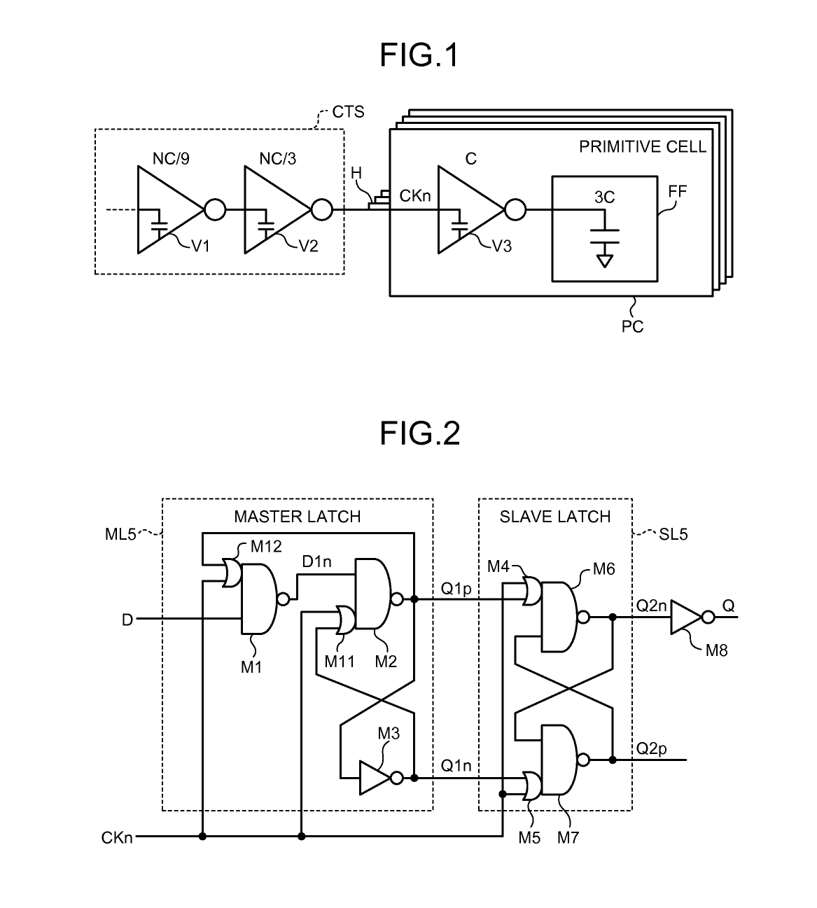

FIG. 1 is a block diagram showing schematically the configuration of a semiconductor integrated circuit according to the first embodiment.

In FIG. 1, in this semiconductor integrated circuit, there are provided a clock tree structure CTS and N number of primitive cells PC (N is a positive integer). The clock tree structure CTS is connected via lines H to the N number of primitive cells PC. The primitive cells PC are circuit elements used in automatic placement and routing. A selection, an arrangement and a connection is executed so as to optimize an area and a signal propagation time etc. by computing for the automatic placement and routing.

At least part of a semiconductor integrated circuit can be formed of only the primitive cells PC and lines connected between the primitive cells PC.

In the clock tree structure CTS, clock buffers V1, V2 are provided. Note that the clock tree structure CTS can form a synchronizing signal circuit. In each primitive cell PC, a negative logic flip-flop FF and one stage of a clock buffer V3 are provided. The negative logic flip-flop FF starts holding data in response to the falling of clock CKn. The clock buffer V3 inputs clock CKn to the negative logic flip-flop FF. The clock buffer V2 is connected, as the preceding stage, to the clock buffer V3, and the clock buffer V1 is connected, as the preceding stage, to the clock buffer V2. Inverters can be used as the clock buffers V1 to V3.

Here, letting 3C be the transistor capacitance driven by clock CKn in the negative logic flip-flop FF, and supposing that the fan-out of a preceding stage being ⅓ of that of the stage subsequent thereto is optimal, the transistor capacitance of the clock buffer V3 is given as C. Because the clock tree structure CTS drives the N number of primitive cells PC, the transistor capacitance of the clock buffer V2 is given as NC/3, and the transistor capacitance of the clock buffer V1 is given as NC/9. Hence, the power consumption of this semiconductor integrated circuit is proportional to NC(4+1/3+1/9 . . . )=4.5NC.

Defining the negative logic flip-flop FF as a primitive cell makes it possible to form logic circuits by an automatic placement and routing technique, thus making the circuit design of semiconductor integrated circuits more efficient. Providing the clock buffer V3 in the primitive cell PC makes it possible to avoid the risk of signal deterioration due to automatic placement and routing while reducing the load to be placed on the synchronizing signal circuit, thus improving the degrees of freedom of placement. Providing the negative logic flip-flop FF in the primitive cell PC also eliminates the need to provide two stages of clock buffers V3 in the primitive cell PC, and thus the power consumption of the semiconductor integrated circuit can be reduced.

### Second Embodiment

FIG. 2 is a block diagram showing the configuration of a flip-flop applied to a semiconductor integrated circuit according to the second embodiment.

In FIG. 2, in this flip-flop, there are provided a master latch ML5, a slave latch SL5, and an inverter M8. The master latch ML5 can read in data D depending on clock CKn. The slave latch SL5 can hold the data read into the master latch ML5 depending on clock CKn.

In the master latch ML5, there are provided NAND circuits M1, M2, OR circuits M12, M11, and an inverter M3. In the slave latch SL5, there are provided OR circuits M4, M5 and NAND circuits M6, M7. The output of the NAND circuit M2 is input to a first input terminal of the OR circuit M12; clock CKn is input to a second input terminal of the OR circuit M12; and a second input terminal of the NAND circuit M1 is connected to the output terminal of the OR circuit M12. The output of the inverter M3 is input to a first input terminal of the OR circuit M11; clock CKn is input to a second input terminal of the OR circuit M11; and a second input terminal of the NAND circuit M2 is connected to the output terminal of the OR circuit M11. Data D is input to a first input terminal of the NAND circuit M1, and the output of the OR circuit M12 is input to a second input terminal of the NAND circuit M1. The output of the NAND circuit M1 is input to a first input terminal of the NAND circuit M2, and the output of the OR circuit M11 is input to a second input terminal of the NAND circuit M2. The output of the NAND circuit M2 is input to the inverter M3. The output of the NAND circuit M2 is input to a first input terminal of the OR circuit M4, and clock CKn is input to a second input terminal of the OR circuit M4. The output of the inverter M3 is input to a first input terminal of the OR circuit M5, and clock CKn is input to a second input terminal of the OR circuit M5. The output of the OR circuit M4 is input to a first input terminal of the NAND circuit M6. The output of the OR circuit M5 is input to a first input terminal of the NAND circuit M7; the output of the NAND circuit M6 is input to a second input terminal of the NAND circuit M7; and a second input terminal of the NAND circuit M6 is connected to the output terminal of the NAND circuit M7. The output of the NAND circuit M6 is input to the inverter M8.

When clock CKn has risen, data D is read in via the NAND circuit M1, and data D1n that is inverted data D is output to the NAND circuit M2. Then the NAND circuit M2 inverts data D1n to produce data Q1p, which the inverter M3 inverts to produce data Q1n. The data Q1n is returned via the OR circuit M11 to the NAND circuit M2.

The data Q1p is read via the OR circuit M4 into the NAND circuit M6. Then the NAND circuit M6 inverts data Q1p to produce data Q2n, which the inverter M8 inverts to produce data Q. The NAND circuit M7 inverts data Q2n to produce data Q2p, which is returned to the NAND circuit M6.

Then, when clock CKn has fallen, data Q1p is returned via the OR circuit M12 to the NAND circuit M1 while data Q1n is returned via the OR circuit M11 to the NAND circuit M2, so that data D is held in the master latch ML5. Data Q1p is input via the OR circuit M4 to the NAND circuit M6, and the NAND circuit M6 inverts data Q1p to produce data Q2n, and the NAND circuit M7 inverts data Q2n to produce data Q2p, and data Q2p is returned to the NAND circuit M6, so that data D is held in the slave latch SL5.

Defining the flip-flop of FIG. 2 in place of the negative logic flip-flop FF of FIG. 1 as a primitive cell makes it possible to form logic circuits by an automatic placement and routing technique, thus making the circuit design of semiconductor integrated circuits more efficient.

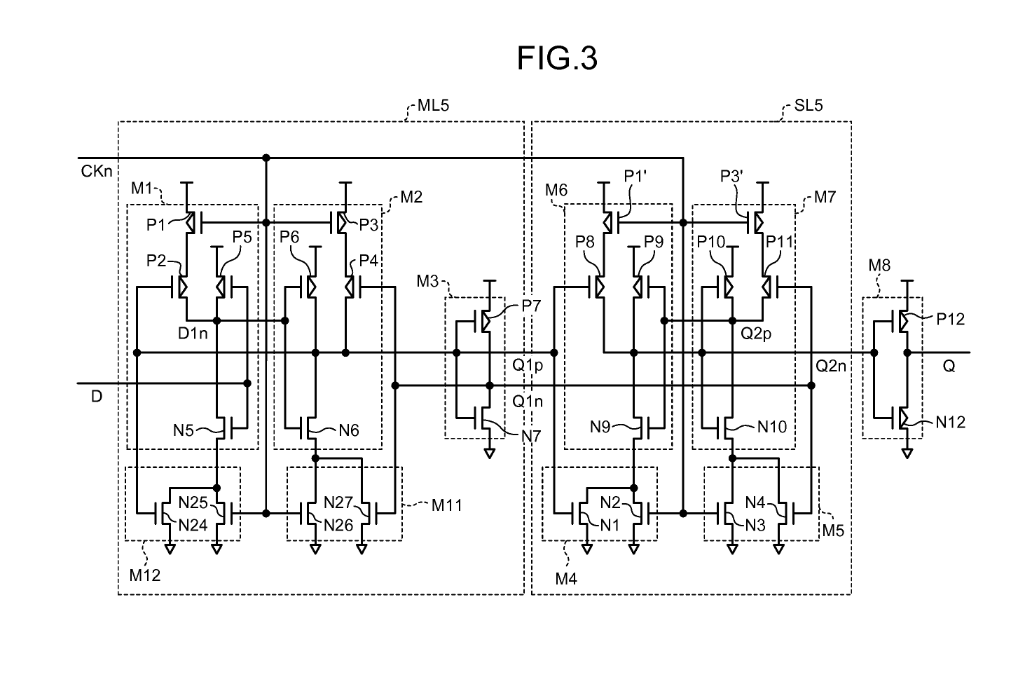

FIG. 3 is a circuit diagram showing a specific example of the flip-flop of FIG. 2.

In FIG. 3, in the NAND circuit M1, there are provided P channel transistors P1, P2, P5 and an N channel transistor N5. In the NAND circuit M2, there are provided P channel transistors P3, P4, P6 and an N channel transistor N6. In the inverter M3, there are provided a P channel transistor P7 and an N channel transistor N7. In the OR circuit M4, N channel transistors N1, N2 are provided. In the OR circuit M5, N channel transistors N3, N4 are provided. In the NAND circuit M6, there are provided P channel transistors P1′, P8, P9 and an N channel transistor N9. In the OR circuit M12, N channel transistors N24, N25 are provided. In the OR circuit M11, N channel transistors N26, N27 are provided. In the NAND circuit M7, there are provided P channel transistors P3′, P10, P11 and an N channel transistor N10. In the inverter M8, there are provided a P channel transistor P12 and an N channel transistor N12.

The P channel transistors P1, P2 are connected in series. The P channel transistors P3, P4 are connected in series. The P channel transistors P1′, P8 are connected in series. The P channel transistors P3′, P11 are connected in series. The P channel transistor P5 and the N channel transistor N5 are connected in series. The P channel transistor P6 and the N channel transistor N6 are connected in series. The P channel transistor P7 and the N channel transistor N7 are connected in series. The P channel transistor P9 and the N channel transistor N9 are connected in series. The P channel transistor P10 and the N channel transistor N10 are connected in series. The P channel transistor P12 and the N channel transistor N12 are connected in series. The N channel transistors N1, N2 are connected in parallel to the drain of the N channel transistor N9. The N channel transistors N3, N4 are connected in parallel to the drain of the N channel transistor N10. The N channel transistors N24, N25 are connected in parallel to the drain of the N channel transistor N5. The N channel transistors N26, N27 are connected in parallel to the drain of the N channel transistor N6. Clock CKn is input to the gates of the N channel transistors N25, N26. The gate of the N channel transistors N24 is connected to the gate of the P channel transistor P2. The gate of the N channel transistors N27 is connected to the gate of the P channel transistor P4.

Clock CKn is input to the gates of the P channel transistors P1, P1′, P3, P3′ and of the N channel transistors N2, N3. Data D is input to the gates of the P channel transistor P5 and the N channel transistor N5. The gates of the P channel transistor P6 and the N channel transistor N6 are connected to the drains of the P channel transistors P2, P5 and of the N channel transistor N5. The gates of the P channel transistors P2, P7, P8 and of the N channel transistors N1, N7 are connected to the drains of the P channel transistors P4, P6 and of the N channel transistor N6. The gates of the P channel transistors P4, P11 and of the N channel transistor N4 are connected to the drains of the P channel transistor P7 and the N channel transistor N7. The gates of the P channel transistors P10, P12 and of the N channel transistors N10, N12 are connected to the drains of the P channel transistors P8, P9 and of the N channel transistor N9. The gates of the P channel transistor P9 and the N channel transistor N9 are connected to the drains of the P channel transistors P10, P11 and of the N channel transistor N10.

### Third Embodiment

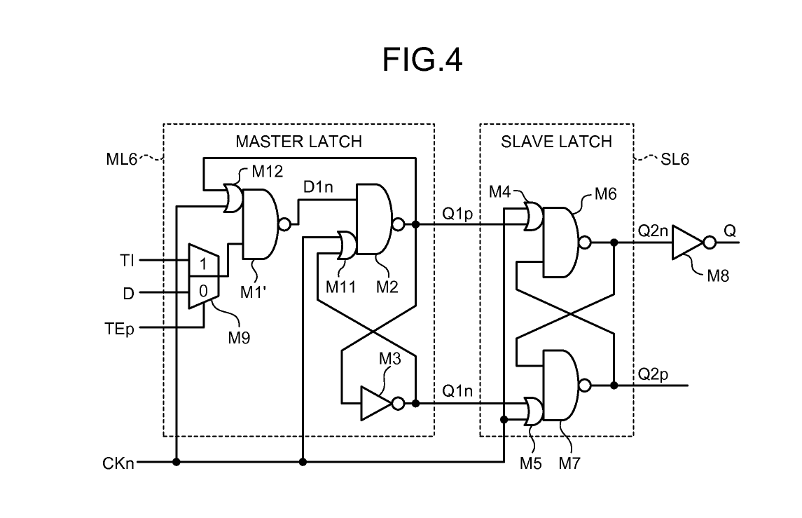

FIG. 4 is a block diagram showing the configuration of a flip-flop applied to a semiconductor integrated circuit according to the third embodiment.

In FIG. 4, in this flip-flop, there are provided a master latch ML6, a slave latch SL6, and an inverter M8. The master latch ML6 has a configuration where a selector M9 is added to the master latch ML5 of FIG. 2 and where a NAND circuit M1′ is provided instead of the NAND circuit M1. The slave latch SL6 has the same configuration as the slave latch SL5 of FIG. 2.

The selector M9 can select data D or a test signal T1 according to a test enable signal TEp. When the test enable signal TEp is active, instead of data D the test signal T1 is input to the NAND circuit M1′. The operation when the test signal T1 is input to the NAND circuit M1′ is the same as that of the flip-flop of FIG. 2.

Defining the flip-flop of FIG. 4 in place of the negative logic flip-flop FF of FIG. 1 as a primitive cell makes it possible to form logic circuits comprising flip-flops with a test-data selector by an automatic placement and routing technique, thus making the circuit design of semiconductor integrated circuits more efficient.

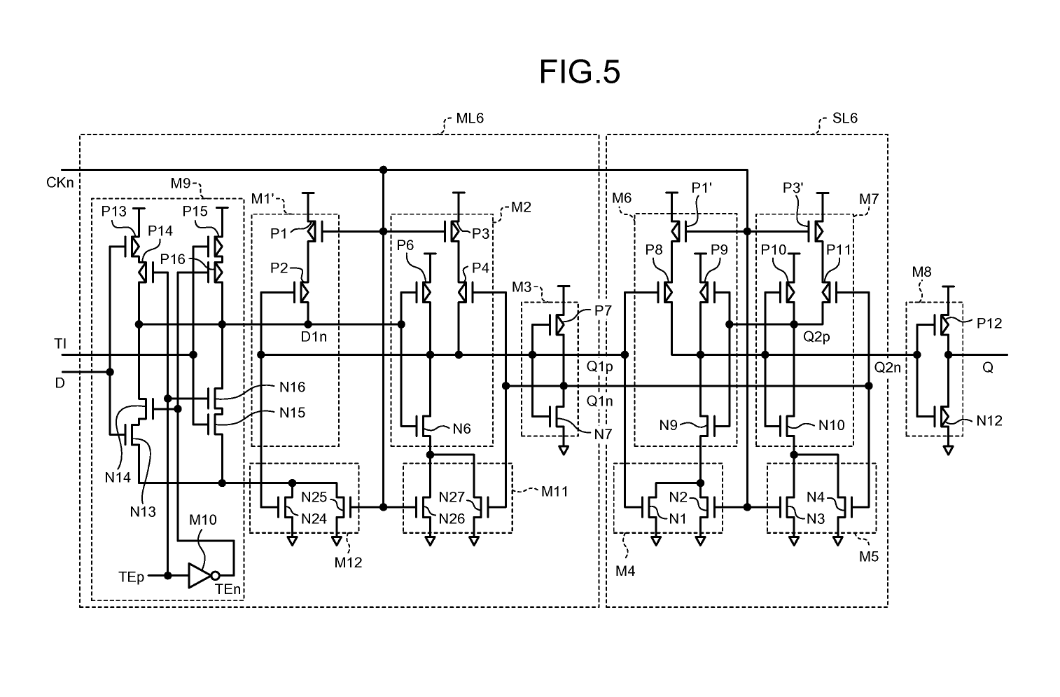

FIG. 5 is a circuit diagram showing a specific example of the flip-flop of FIG. 4.

In FIG. 5, in the selector M9, there are provided P channel transistors P13 to P16, N channel transistors N13 to N16, and an inverter M10. The NAND circuit M1′ has a configuration obtained by removing the P channel transistor P5 and the N channel transistor N5 from the NAND circuit M1 of FIG. 3. In the flip-flop of FIG. 4, the inverter function of the P channel transistor P5 and the N channel transistor N5 is realized by the selector M9.

The P channel transistors P13, P14 and N channel transistors N14, N13 are connected in series. The P channel transistors P15, P16 and N channel transistors N16, N15 are connected in series. The test enable signal TEp is input to the gates of the P channel transistor P14 and N channel transistor N16 and to the inverter M10. The output of the inverter M10 is input to the gates of the P channel transistor P16 and N channel transistor N14. Data D is input to the gates of the P channel transistor P13 and N channel transistor N13. The test signal T1 is input to the gates of the P channel transistor P15 and N channel transistor N15.

The test enable signal TEp is input to the inverter M10, so that an inverted test enable signal TEn is produced. When the test enable signal TEp rises, the P channel transistor P16 and N channel transistor N16 turn on while the P channel transistor P14 and N channel transistor N14 turn off. Hence, an inverter consisting of the P channel transistor P15 and N channel transistor N15 is formed to invert the test signal T1, and thus data D1n is produced. When the test enable signal TEp falls, the P channel transistor P16 and N channel transistor N16 turn off while the P channel transistor P14 and N channel transistor N14 turn on. Hence, an inverter consisting of the P channel transistor P13 and N channel transistor N13 is formed to invert data D, and thus data D1n is produced.

### Fourth Embodiment

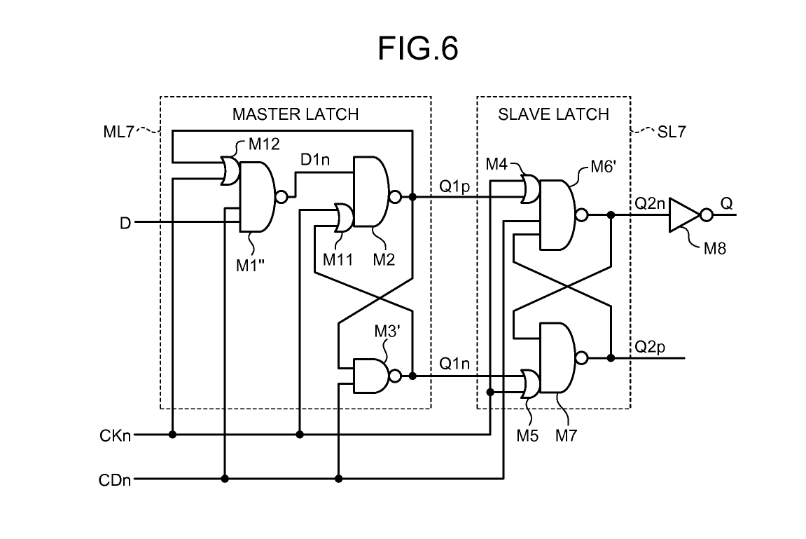

FIG. 6 is a block diagram showing the configuration of a flip-flop applied to a semiconductor integrated circuit according to the fourth embodiment.

In FIG. 6, in this flip-flop, there are provided a master latch ML7, a slave latch SL7, and an inverter M8. The master latch ML7 has a configuration where NAND circuits M1″, M3′ are provided instead of the NAND circuit M1 and the inverter M3 of the master latch ML5 of FIG. 2. The slave latch SL7 has a configuration where a NAND circuit M6′ is provided instead of the NAND circuit M6 of the slave latch SL5 of FIG. 2.

A data clear signal CDn, as well as the inputs to the NAND circuit M1, is input to the NAND circuit M1″. The data clear signal CDn, as well as the input to the inverter M3, is input to the NAND circuit M3′. The data clear signal CDn, as well as the inputs to the NAND circuit M6, is input to the NAND circuit M6′.

When the data clear signal CDn becomes low, data D1n, Q1n, Q2n respectively output from the NAND circuit M1″, M3′, M6′ become high, and data Q1p, Q2p respectively output from the NAND circuit M2, M7 become low. Hence, data Q output from the inverter M8 becomes low, resulting in data of the flip-flop being cleared.

Defining the flip-flop of FIG. 6 in place of the negative logic flip-flop FF of FIG. 1 as a primitive cell makes it possible to form logic circuits comprising flip-flops with a data clear terminal by an automatic placement and routing technique, thus making the circuit design of semiconductor integrated circuits more efficient.

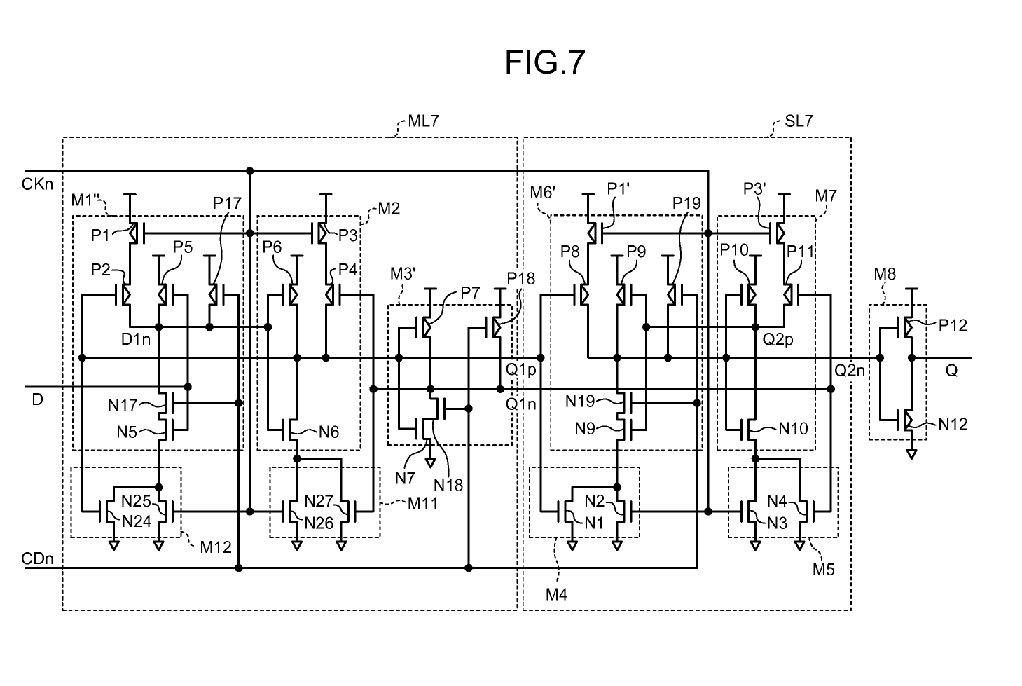

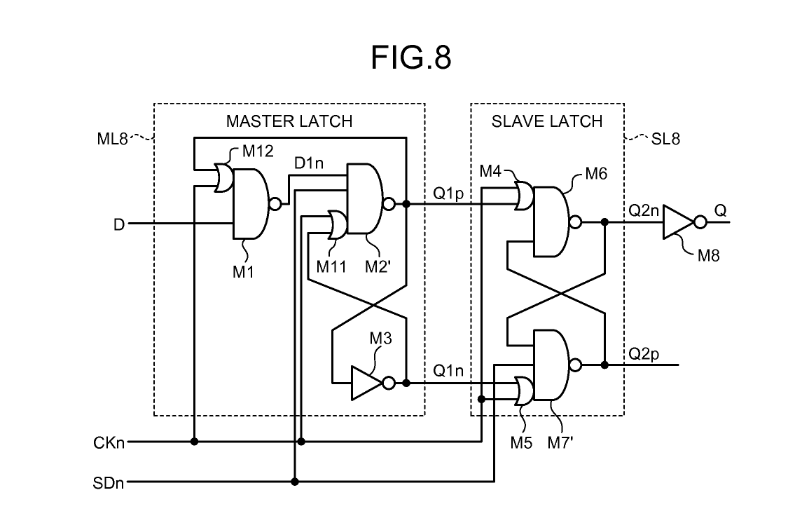

FIG. 7 is a circuit diagram showing a specific example of the flip-flop of FIG. 6.

In FIG. 7, the NAND circuit M1″ has a configuration where a P channel transistor P17 and an N channel transistor N17 are added to the NAND circuit M1. The NAND circuit M3′ has a configuration where a P channel transistor P18 and an N channel transistor N18 are added to the inverter M3. The NAND circuit M6′ has a configuration where a P channel transistor P19 and an N channel transistor N19 are added to the NAND circuit M6.

The N channel transistor N17 is connected between the drains of the P channel transistors P2, P5 and the drain of the N channel transistor N5. The drain of the P channel transistor P17 is connected to the drains of the P channel transistors P2, P5. The N channel transistor N18 is connected between the drain of the P channel transistor P7 and the drain of the N channel transistor N7. The drain of the P channel transistor P18 is connected to the drain of the P channel transistor P7. The N channel transistor N19 is connected between the drains of the P channel transistors P8, P9 and the drain of the N channel transistor N9. The drain of the P channel transistor P19 is connected to the drains of the P channel transistors P8, P9. The data clear signal CDn is input to the gates of the P channel transistors P17 to P19 and of the N channel transistors N17 to N19.

When the data clear signal CDn becomes low, the N channel transistors N17 to N19 turn off, and the P channel transistors P17 to P19 turn on. Hence, data D1n, Q1n, Q2n become high, and data Q1p, Q2p, Q become low, resulting in data of the flip-flop being cleared.

### Fifth Embodiment

FIG. 8 is a block diagram showing the configuration of a flip-flop applied to a semiconductor integrated circuit according to the fifth embodiment.

In FIG. 8, in this flip-flop, there are provided a master latch ML8, a slave latch SL8, and an inverter M8. The master latch ML8 has a configuration where a NAND circuit M2′ is provided instead of the NAND circuit M2 of the master latch ML5 of FIG. 2. The slave latch SL8 has a configuration where a NAND circuit M7′ is provided instead of the NAND circuit M7 of the slave latch SL5 of FIG. 2.

A data set signal SDn, as well as the inputs to the NAND circuit M2, is input to the NAND circuit M2′. The data set signal SDn, as well as the inputs to the NAND circuit M7, is input to the NAND circuit M7′.

When the data set signal SDn becomes low, data D1n, Q1n, Q2n respectively output from the NAND circuit M1, M3, M6 become low, and data Q1p, Q2p respectively output from the NAND circuit M2′, M7′ become high. Hence, data Q output from the inverter M8 becomes high, resulting in data of the flip-flop being set.

Defining the flip-flop of FIG. 8 in place of the negative logic flip-flop FF of FIG. 1 as a primitive cell makes it possible to form logic circuits comprising flip-flops with a data set terminal by an automatic placement and routing technique, thus making the circuit design of semiconductor integrated circuits more efficient.

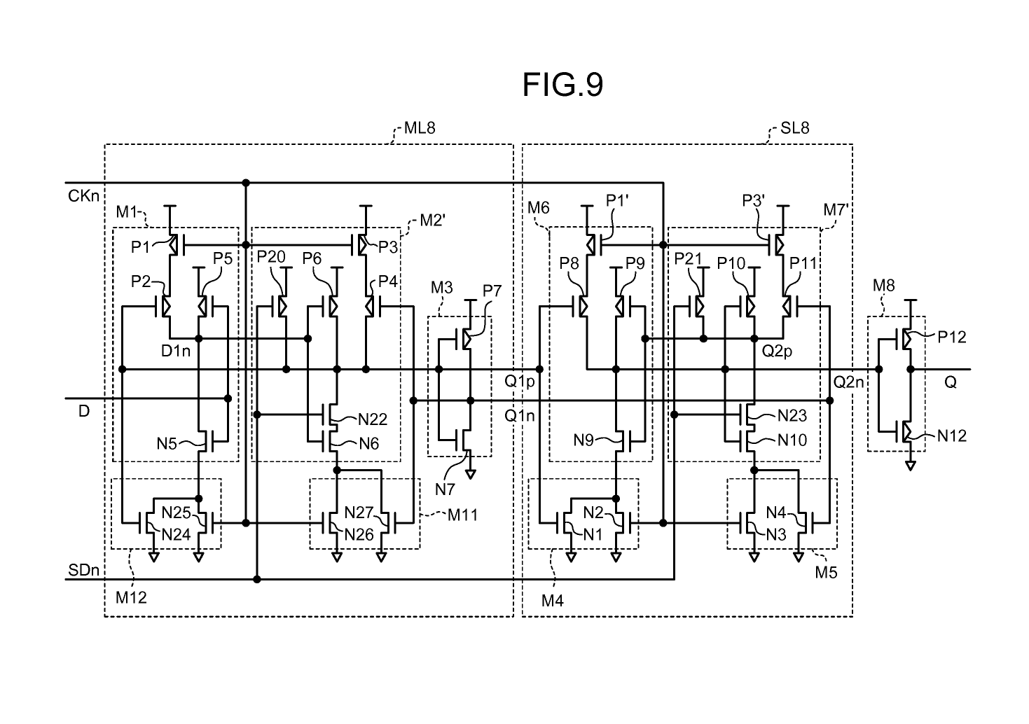

FIG. 9 is a circuit diagram showing a specific example of the flip-flop of FIG. 8.

In FIG. 9, the NAND circuit M2′ has a configuration where a P channel transistor P20 and an N channel transistor N22 are added to the NAND circuit M2. The NAND circuit M7′ has a configuration where a P channel transistor P21 and an N channel transistor N23 are added to the NAND circuit M7.

The N channel transistor N22 is connected between the drains of the P channel transistors P4, P6 and the drain of the N channel transistor N6. The drain of the P channel transistor P20 is connected to the drains of the P channel transistors P4, P6. The N channel transistor N23 is connected between the drains of the P channel transistors P10, P11 and the drain of the N channel transistor N10. The drain of the P channel transistor P21 is connected to the drains of the P channel transistors P10, P11. The data set signal SDn is input to the gates of the P channel transistors P20, P21 and of the N channel transistors N22, N23.

When the data set signal SDn becomes low, the N channel transistors N22, N23 turn off, and the P channel transistors P20, P21 turn on. Hence, data D1n, Q1n, Q2n become low, and data Q1p, Q2p, Q become high, resulting in data of the flip-flop being set.

### Sixth Embodiment

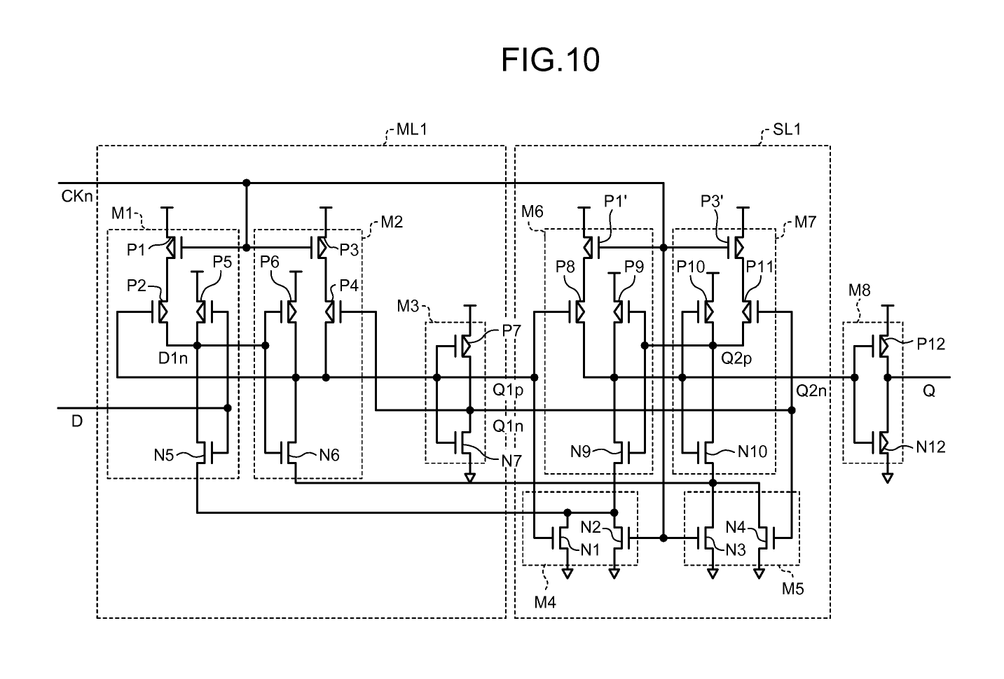

FIG. 10 is a circuit diagram showing the configuration of a flip-flop applied to a semiconductor integrated circuit according to the sixth embodiment.

In FIG. 10, in this flip-flop, there are provided a master latch ML1, a slave latch SL1, and an inverter M8. The master latch ML1 has a configuration obtained by removing the OR circuits M12, M11 from the master latch ML5 of FIG. 3. The slave latch SL1 has the same configuration as the slave latch SL5 of FIG. 3. The N channel transistors N1, N2 are connected in parallel to the drain of the N channel transistor N5. The N channel transistors N3, N4 are connected in parallel to the drain of the N channel transistor N6. The operation of this flip-flop is the same as that of the flip-flop of FIG. 3.

Because the master latch ML1 and the slave latch SL1 share the OR circuits M4, M5, the circuit scale of the flip-flop can be reduced, and the power consumption can be reduced.

### Seventh Embodiment

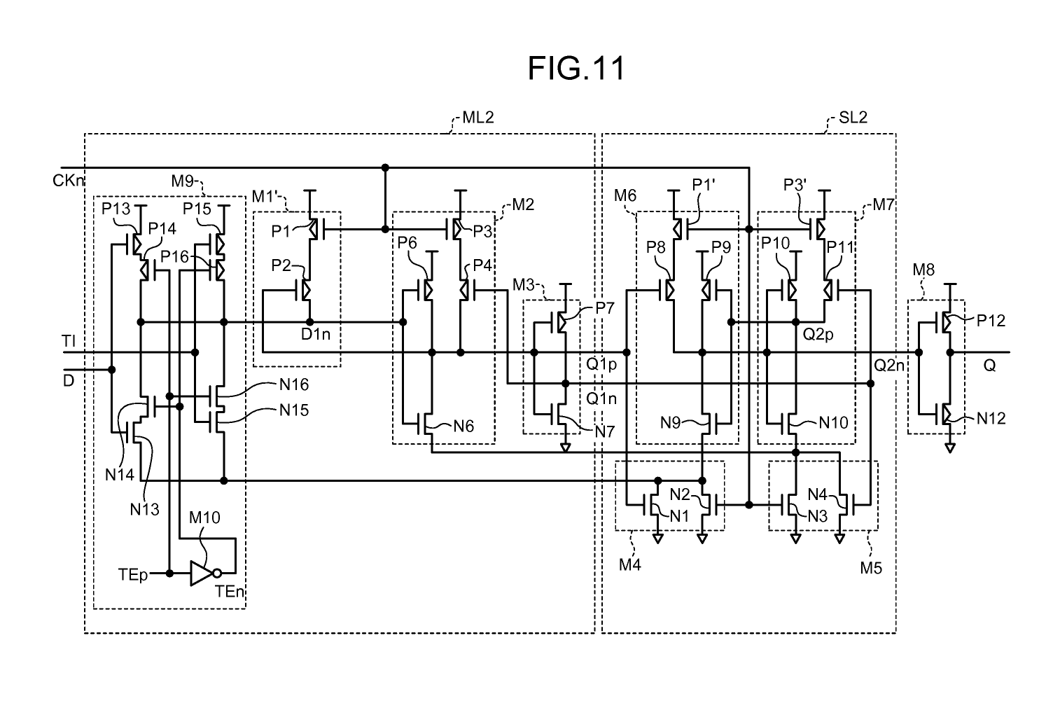

FIG. 11 is a circuit diagram showing the configuration of a flip-flop applied to a semiconductor integrated circuit according to the seventh embodiment.

In FIG. 11, in this flip-flop, there are provided a master latch ML2, a slave latch SL2, and an inverter M8. The master latch ML2 has a configuration where a selector M9 is added to the master latch ML1 of FIG. 10 and where a NAND circuit M1′ is provided instead of the NAND circuit M1. The slave latch SL2 has the same configuration as the slave latch SL1 of FIG. 10. The operation of this flip-flop is the same as that of the flip-flop of FIG. 5.

Defining the flip-flop of FIG. 11 in place of the negative logic flip-flop FF of FIG. 1 as a primitive cell makes it possible to form logic circuits comprising flip-flops with a test data selector by an automatic placement and routing technique, thus making the circuit design of semiconductor integrated circuits more efficient.

Further, because the master latch ML2 and the slave latch SL2 share the OR circuits M4, M5, the circuit scale of the flip-flop can be reduced, and the power consumption can be reduced.

### Eighth Embodiment

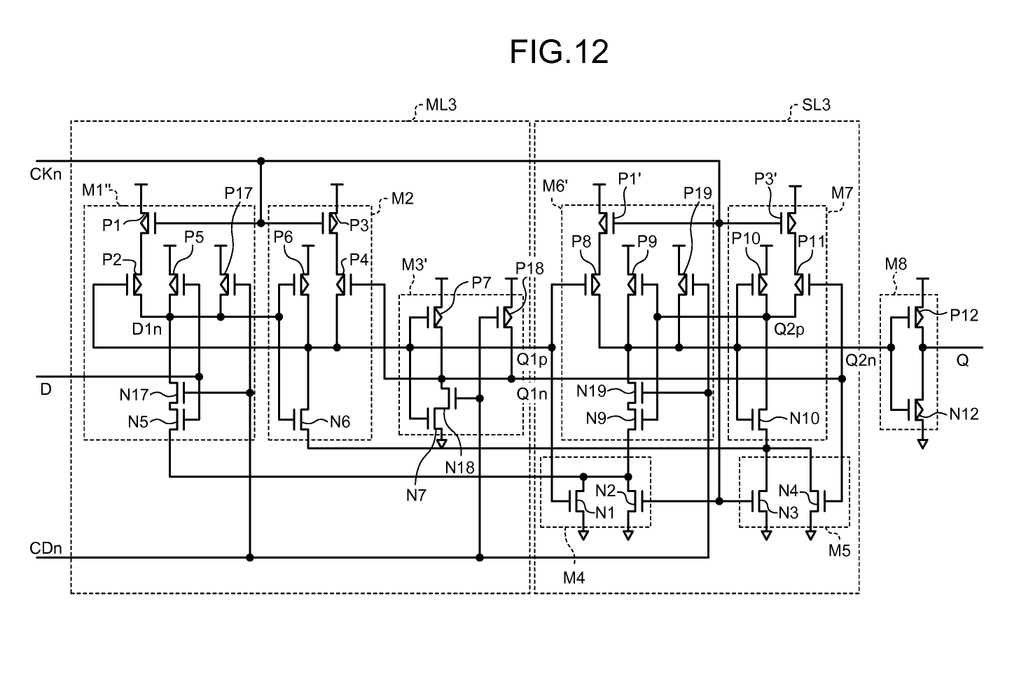

FIG. 12 is a circuit diagram showing the configuration of a flip-flop applied to a semiconductor integrated circuit according to the eighth embodiment.

In FIG. 12, in this flip-flop, there are provided a master latch ML3, a slave latch SL3, and an inverter M8. The master latch ML3 has a configuration where NAND circuits M1″, M3′ are provided instead of the NAND circuit M1 and inverter M3 of the master latch ML1 of FIG. 10. The slave latch SL3 has a configuration where a NAND circuit M6′ is provided instead of the NAND circuit M6 of the slave latch SL1 of FIG. 10. The operation of this flip-flop is the same as that of the flip-flop of FIG. 7.

Defining the flip-flop of FIG. 12 in place of the negative logic flip-flop FF of FIG. 1 as a primitive cell makes it possible to form logic circuits comprising flip-flops with a data clear terminal by an automatic placement and routing technique, thus making the circuit design of semiconductor integrated circuits more efficient.

Further, because the master latch ML3 and the slave latch SL3 share the OR circuits M4, M5, the circuit scale of the flip-flop can be reduced, and the power consumption can be reduced.

### Ninth Embodiment

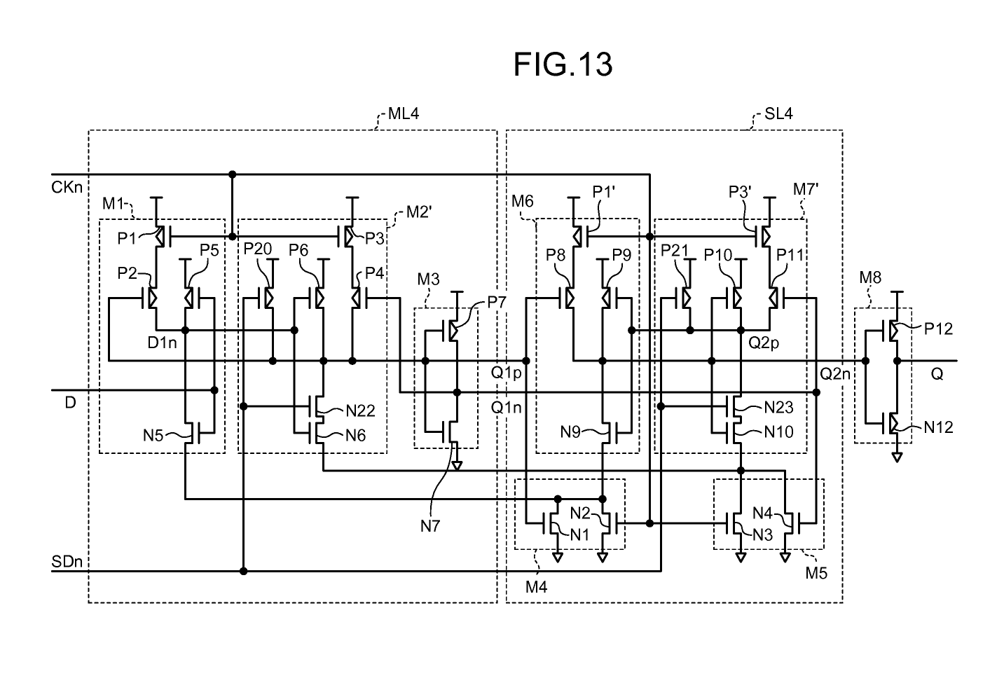

FIG. 13 is a circuit diagram showing the configuration of a flip-flop applied to a semiconductor integrated circuit according to the ninth embodiment.

In FIG. 13, in this flip-flop, there are provided a master latch ML4, a slave latch SL4, and an inverter M8. The master latch ML4 has a configuration where NAND circuit M2′ is provided instead of the NAND circuit M2 of the master latch ML1 of FIG. 10. The slave latch SL4 has a configuration where a NAND circuit M7′ is provided instead of the NAND circuit M7 of the slave latch SL1 of FIG. 10. The operation of this flip-flop is the same as that of the flip-flop of FIG. 9.

Defining the flip-flop of FIG. 13 in place of the negative logic flip-flop FF of FIG. 1 as a primitive cell makes it possible to form logic circuits comprising flip-flops with a data set terminal by an automatic placement and routing technique, thus making the circuit design of semiconductor integrated circuits more efficient.

Further, because the master latch ML4 and the slave latch SL4 share the OR circuits M4, M5, the circuit scale of the flip-flop can be reduced, and the power consumption can be reduced.

### Tenth Embodiment

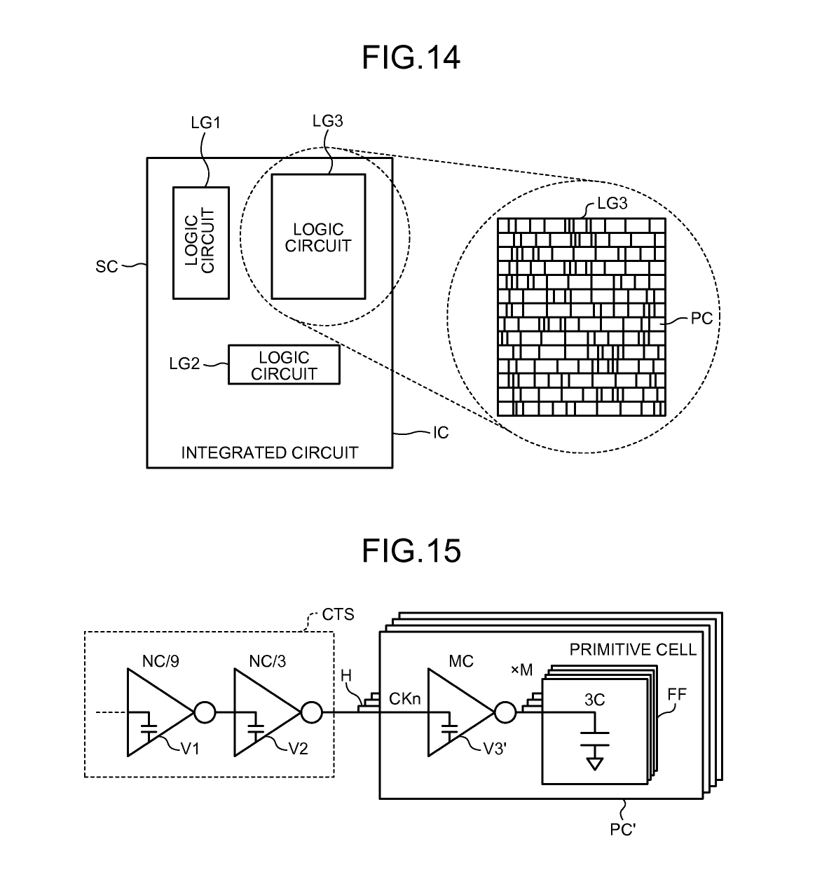

FIG. 14 is a plan view showing an example layout of primitive cells in a semiconductor integrated circuit according to the tenth embodiment.

In FIG. 14, an integrated circuit IC is formed on a semiconductor chip SC. Logic circuits LG1 to LG3 are provided in the integrated circuit IC. In the logic circuit LG3, primitive cells PC are automatically placed and routed. Providing the negative logic flip-flop FF and one stage of the clock buffer V3 in the primitive cell makes it possible to avoid the risk of signal deterioration due to automatic placement and routing while achieving a reduction in the power consumption of the integrated circuit IC.

### Eleventh Embodiment

FIG. 15 is a block diagram showing schematically the configuration of a semiconductor integrated circuit according to the eleventh embodiment.

In FIG. 15, in this semiconductor integrated circuit, there are provided a clock tree structure CTS and N/M number of primitive cells PC′ (N/M is a positive integer). The clock tree structure CTS is connected via lines H to the N number of primitive cells PC′.

In each primitive cell PC′, M number of negative logic flip-flops FF (M is a positive integer) and one stage of a clock buffer V3′ are provided. The clock buffer V3′ inputs clock CKn to the M number of negative logic flip-flops FF. The clock buffer V2 is connected, as the preceding stage, to the clock buffer V3′, and the clock buffer V1 is connected, as the preceding stage, to the clock buffer V2. An inverter can be used as the clock buffer V3′.

Here, letting 3C be the transistor capacitance driven by clock CKn in the negative logic flip-flop FF, and supposing that the fan-out of a preceding stage being ⅓ of that of the stage subsequent thereto is optimal, the transistor capacitance of the clock buffer V3′ is given as MC. Because the clock tree structure CTS drives the N/M number of primitive cells PC′, the transistor capacitance of the clock buffer V2 is given as NC/3, and the transistor capacitance of the clock buffer V1 is given as NC/9. Hence, the power consumption of this semiconductor integrated circuit is proportional to NC(4+⅓+ 1/9 . . . )=4.5NC.

Defining the M number of negative logic flip-flops FF as a primitive cell makes it possible to form logic circuits by an automatic placement and routing technique, thus making the circuit design of semiconductor integrated circuits more efficient. Providing the clock buffer V3′ in the primitive cell PC′ makes it possible to avoid the risk of signal deterioration due to automatic placement and routing while reducing the load to be placed on the synchronizing signal circuit, thus improving the degrees of freedom of placement. Providing the M number of negative logic flip-flops FF in the primitive cell PC′ also eliminates the need to provide two stages of clock buffers V3′ in the primitive cell PC′, and thus the power consumption of the semiconductor integrated circuit can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit comprising:
primitive cells which are circuit elements used in automatic placement and routing by computing; and
lines connecting to the primitive cells,
wherein the primitive cell comprises:
a negative logic flip-flop; and
one stage of a clock buffer that inputs a clock to the negative logic flip-flop.

2. The semiconductor integrated circuit according to claim 1, wherein the negative logic flip-flop is a flip-flop with a test data selector.

3. The semiconductor integrated circuit according to claim 1, wherein the negative logic flip-flop is a flip-flop with a data clear terminal.

4. The semiconductor integrated circuit according to claim 1, wherein the negative logic flip-flop is a flip-flop with a data set terminal.

5. The semiconductor integrated circuit according to claim 1, wherein the negative logic flip-flop comprises:
a master latch to read in data depending on the clock; and
a slave latch to hold the data read into the master latch depending on the clock.

6. The semiconductor integrated circuit according to claim 5, wherein the master latch and the slave latch share transistors of OR circuits to which the clock is input.

7. The semiconductor integrated circuit according to claim 1, wherein the clock buffer is an inverter.

8. The semiconductor integrated circuit according to claim 1, comprising a clock tree structure connected, as a preceding stage, to the primitive cells via the lines to supply the clock to the primitive cells.

9. The semiconductor integrated circuit according to claim 8, wherein the clock tree structure is connected to N number of primitive cells (N is a positive integer) via the lines.

10. The semiconductor integrated circuit according to claim 8, wherein the primitive cell comprises M number of negative logic flip-flops (M is a positive integer), and the clock tree structure inputs the clock to the M number of negative logic flip-flops.

11. The semiconductor integrated circuit according to claim 1, wherein the primitive cells are automatically placed and routed to form a logic circuit.

12. The semiconductor integrated circuit according to claim 1, wherein at least part of the integrated circuit is formed of only the primitive cells and lines connected between the primitive cells.

13. The semiconductor integrated circuit according to claim 1, wherein the negative logic flip-flop comprises:
a first NAND circuit of which data is input to a first input terminal;
a second NAND circuit of which the output of the first NAND circuit is input to a first input terminal;
a first inverter to which the output of the second NAND circuit is input;
a first OR circuit of which the output of the second NAND circuit is input to a first input terminal and the clock is input to a second input terminal and whose output terminal is connected to a second input terminal of the first NAND circuit;
a second OR circuit of which the output of the first inverter is input to a first input terminal and the clock is input to a second input terminal and whose output terminal is connected to a second input terminal of the second NAND circuit;
a third NAND circuit of which the output of the first OR circuit is input to a first input terminal and the output of the second NAND circuit is input to a second input terminal;
a fourth NAND circuit of which the output of the second OR circuit is input to a first input terminal and the output of the first inverter is input to a second input terminal; and
a second inverter to which the output of the third NAND circuit is input.

14. The semiconductor integrated circuit according to claim 13, wherein the negative logic flip-flop comprises a selector that selects the data or a test signal according to a test enable signal.

15. The semiconductor integrated circuit according to claim 13, wherein a data clear signal is input to the third NAND circuit.

16. The semiconductor integrated circuit according to claim 13, wherein a data set signal is input to the fourth NAND circuit.

17. The semiconductor integrated circuit according to claim 1, wherein the negative logic flip-flop comprises:
a first NAND circuit of which data is input to a first input terminal;
a second NAND circuit of which the output of the first NAND circuit is input to a first input terminal;
a first OR circuit of which the output of the second NAND circuit is input to a first input terminal and the clock is input to a second input terminal and whose output terminal is connected to a second input terminal of the first NAND circuit;
a first inverter to which the output of the second NAND circuit is input;
a second OR circuit of which the output of the first inverter is input to a first input terminal and the clock is input to a second input terminal and whose output terminal is connected to a second input terminal of the second NAND circuit;
a third OR circuit of which the output of the second NAND circuit is input to a first input terminal and the clock is input to a second input terminal;
a fourth OR circuit of which the output of the first inverter is input to a first input terminal and the clock is input to a second input terminal;
a third NAND circuit of which the output of the third OR circuit is input to a first input terminal;
a fourth NAND circuit of which the output of the fourth OR circuit is input to a first input terminal and the output of the third NAND circuit is input to a second input terminal and whose output terminal is connected to a second input terminal of the third NAND circuit; and
a second inverter to which the output of the third NAND circuit is input.

18. The semiconductor integrated circuit according to claim 17, wherein the negative logic flip-flop comprises a selector that selects the data or a test signal according to a test enable signal.

19. The semiconductor integrated circuit according to claim 17, wherein a data clear signal is input to the third NAND circuit.

20. The semiconductor integrated circuit according to claim 17, wherein a data set signal is input to the fourth NAND circuit.
